(19) United States
(12) Patent Application Publication
(10) Pub. No.: US 2009/0277671 A1
(43) Pub. Date: Nov. 12, 2009

(54) GLASS PANE HAVING SOLDERED ELECTRICAL TERMINAL CONNECTIONS

(75) Inventor: Herbert Hahn, Wulfen (DE)

Correspondence Address: BUCHANAN, INGERSOLL & ROONEY PC, POST OFFICE BOX 1404, ALEXANDRIA, VA, 22313-1404, US

(73) Assignee: PILKINGTON AUTOMOTIVRE DEUTSCHLAND GmbH, Witten (DE)

(21) Appl. No.: 12/296,785

(22) PCT Filed: Apr. 12, 2007
(86) PCT No.: PCT/EP07/53545

§ 371 Date: Nov. 20, 2008

(30) Foreign Application Priority Data
Apr. 12, 2006 (DE) 102006017675.8

(51) Int. Cl. H05K 1/09; H05K 1/03; B23K 37/00

(52) U.S. Cl. 174/257; 174/258; 228/136

(57) ABSTRACT

A glass pane having at least one electrical functional element is provided. The functional element comprises at least one electrical conductor and at least one terminal area located at an end of the electrical conductor, wherein the electrical conductor and the terminal area are formed from an electrically conductive layer deposited on a surface of the glass pane. A terminal wire is connected to the at least one terminal area by a soldered joint by way of a metal block having a flat contact area, and the flat contact area is soldered on a corresponding terminal area. A method for forming such a connection is also disclosed.

The invention relates to a glass pane, preferably used for motor vehicles, having at least one electrical functional element, wherein the functional element comprises at least one electrical conductor and at least one terminal area formed at an end of the electrical conductor, wherein the electrical conductor and the terminal area consist of an electrically conductive layer deposited on a glass pane surface, and wherein a terminal wire is connected to the terminal area by means of a soldered joint. Furthermore, the invention relates to a method of producing an electrical terminal connection.

A functional element shall be understood here to mean a functional element which comprises at least one conductive layer deposited on the glass pane with a thick-film technology or a thin-film technology. Examples of such functional elements are resistive heating conductors, alarm conductors and antenna conductors. A glass pane with a functional element of the type mentioned at the outset is used for example as a heatable pane in windscreens for motor vehicles, wherein the electrical conductor is arranged as a heating element in the screen wiper heating field in the lower area of the windscreen. The heatable pane comprises here a laminated glass pane consisting of at least two bent float glass panes, between which at least one plastic film (e.g. made of PVB) is inserted. These glass panes and films are firmly joined together by thermal processes. A conductive layer is deposited on one of the internal or external glass surfaces and structured in such a way that at least one heating conductor and at least two terminal areas located at the ends of the heating conductor are formed. A plurality of heating conductors connected in parallel are often formed between the terminal areas. In order to produce the heating conductor and the terminal areas, a silver-containing paste for example is printed by a screen printing process onto the glass surface and then fired. When the conductive layer is deposited on an external surface of the laminate, the terminal areas are arranged to be freely accessible and usually at the edge of the laminated glass pane. If the conductive layer is deposited on an internal glass surface of one of the glass panes, the respective other glass pane is usually provided with a recess in the region of the terminal areas, in such a way that the terminal areas remain freely accessible.

In many cases, terminal wires are soldered onto the terminal areas. The terminal wires usually comprise a bundle of thin metal cores (so-called flex wire), which are surrounded by a plastic insulation and which increases the mechanical flexibility of the terminal wires. The terminal areas are usually pre-tinned, and in order to produce a soldered joint between the terminal wires and the terminal areas, the plastic insulation at the ends of the terminal wires is removed (after pre-tinning of the terminal wires, as the case may be) and the ends of the terminal wires are soldered onto the terminal areas. This usually takes place manually.

In order to avoid a defect in the further processing of the laminated glass pane, such as a windscreen, the electrical and mechanical connection between the terminal wires and the terminal areas of the heating element must be capable of withstanding mechanical loads. In particular, tearing-off of the terminal wires or fracturing of the conductive layer must not occur in the presence of normal mechanical loading. A minimum pull-off force of 30 N is required for example for a heating field terminal. It has emerged that, with the usual dimensions of the terminal areas and glass thicknesses, the soldered joint produced in the aforementioned manner between the terminal wires and the terminal areas of the heating element is not always able to withstand these loads. In particular, the required minimum pull-off forces of 30 N are not always achieved.

In order to improve the quality of the soldered joint, it has been proposed to fix (e.g. to weld) the terminal wires onto a metal foil or a thin metal sheet and then to solder this relatively large-area composite (consisting of terminal wires and metal foil or thin metal sheet) onto the terminal areas of the heating element. However, this structure likewise did not always exhibit the required tear-off strength. A terminal design of this kind, moreover, is time-consuming (and expensive) and requires large-dimensioned terminal areas, for which adequate space is not always available.

The problem of the invention is therefore to improve the mechanical strength of the electrical terminals in a cost-effective manner, in particular to increase the tear-off strengths.

This problem is solved according to the invention by a glass pane with at least one electrical functional element with the features of claim 1 and a method of producing an electrical terminal connection with the features of claim 23.

A glass pane with an electrical functional element of the type mentioned at the outset is characterised according to the invention in that the at least one terminal wire is fixed to a metal block with a flat contact area and that the flat contact area is soldered on the terminal area.

Metal block is understood here to mean a metallic body, which may be hollow, and which has the good electrical and thermal conductivity usual with metals. The external dimensions of the metal block lie roughly in the same order of magnitude in all three spatial dimensions, i.e. with which no dimension amounts to a tenth or less than another dimension in an orthogonal direction. Preferably, the dimensions in the directions orthogonal to one another differ by no more than a factor 5. A flat contact area is understood here to mean a contact area whose flatness must be sufficient, with a relatively small thickness of the solder layer arranged in between (of, for example, less than 0.2 mm), to enable a joint with the terminal area arranged beneath such that said joint extends over the whole area.

It has been shown that, by fixing such a metal block with a flat contact area to the terminal wire and by soldering-on the flat contact area of the metal block, a tear-off strength of well over 100 N can be achieved. This can attributed to the thermal buffer effect of the metal block and the reduced thermal loading of the glass surface due to the heat distribution (reduction of local temperature peaks). These will be greater than for the thin foil of the prior art. If, in addition, a relatively low soldering temperature is selected, the soldered joint can be produced with the avoidance of high (temporal and local) temperature gradients. This reduces microcracks in the glass and increases the tear-off strength.

In a preferred embodiment of the glass pane according to the invention, the metal block is a bending-resistant metal block. A “bending-resistant metal block” is understood here to mean a metal block which, with one-sided application of the pulling forces, experiences virtually no bending in the presence of the pulling forces occurring here on the terminal wire in the order of magnitude of up to 100 N and with the existing dimensions (terminal areas of a few millimetres width and length) and can thus distribute the forces acting at the fixed terminal wire over the whole contact area.

This preferred embodiment is based on the experience that a markedly increased tear-off strength can be achieved by fixing a relatively rigid metal block at the end of the terminal wire and by the large-area soldering of this metal block onto the terminal area. The metal block contributes here in several ways to an increase in the tear-off strength: (i) it changes the temporal and local heat distribution and thus the microcrack formation and (ii) it changes the force distribution acting at the soldered joint—metal-containing layer—glass surface interfaces when the terminal wire is pulled.

In a preferred embodiment, the contact area of the metal block has a size of at least 10 mm². The contact area can for example be oval, but in the case of the preferred embodiment is of approximately rectangular shape and at least 3 mm wide and at least 4 mm long. The maximum size of the contact area is preferably about 50 mm².

The terminal wire may be welded, glued or soldered on a surface of the metal block lying opposite the contact area. In a preferred embodiment of the invention, the terminal wire is led up to the metal block in a plane essentially parallel to the contact area (lies in or on the metal block) and leaves the metal block laterally. The terminal wire is preferably surrounded by the metal block, for example glued or soldered into a groove or hole. Preferably, however, a metal sleeve is crimped onto the terminal wire in such a way that a metal block of the desired shape is thereby formed.

For example, flex wire (i.e. a bundle of thin metal cores) is used for the terminal wires, onto which a pre-tinned metal sleeve with a wall thickness of preferably approx. 0.5-1 mm is crimped, in such a way that a metal block with an approximately rectangular cross-section and at least 1 mm thickness (preferably at least 1.5 mm thickness) is formed. The dimension of the contact area of the metal block in the longitudinal direction of the terminal wire amounts to at least 4 mm, preferably at least 5 mm, and the dimension of the contact area of the metal block at right angles to the longitudinal direction of the terminal wire amounts to at least 3 mm, preferably at least 4 mm. It has been shown that a particularly tear-resistant soldered joint to the terminal area can be produced with a metal block crimped onto copper flex wire and made from a copper alloy with a tinned surface in the stated dimensional ranges, the conductive layer of the terminal area being preferably a metal-containing layer with a silver proportion of at least 50 at. % produced in a screen-printing/firing process.

In the inventive method of producing an electrical terminal connection to an electrical functional element of a glass pane, wherein the functional element comprises at least one electrical conductor and at least one terminal area located at an end of the electrical conductor and the electrical conductor and the terminal area consist of an electrically conductive layer deposited on a pane surface, first of all at least one terminal wire is provided for each terminal area (with which contact is to be made) and a bending-resistant metal block with a flat contact area is fixed to one end of the terminal wire. Soldering tin is then deposited onto the terminal area of the functional element and/or the contact area of the metal block. Finally, the metal block is placed and pressed with its contact area onto the terminal area and the soldering tin is thereby fused and then allowed to cool, so that a soldered joint with a thin solder layer is formed between the terminal area and the contact area. The solder layer between the contact area and the terminal area is preferably less than 0.2 mm thick.

Advantageous and/or preferred embodiments of the invention are characterised in the sub-claims.

The invention is explained below in greater detail with the aid of a preferred example of embodiment represented in the drawings. In the drawings:

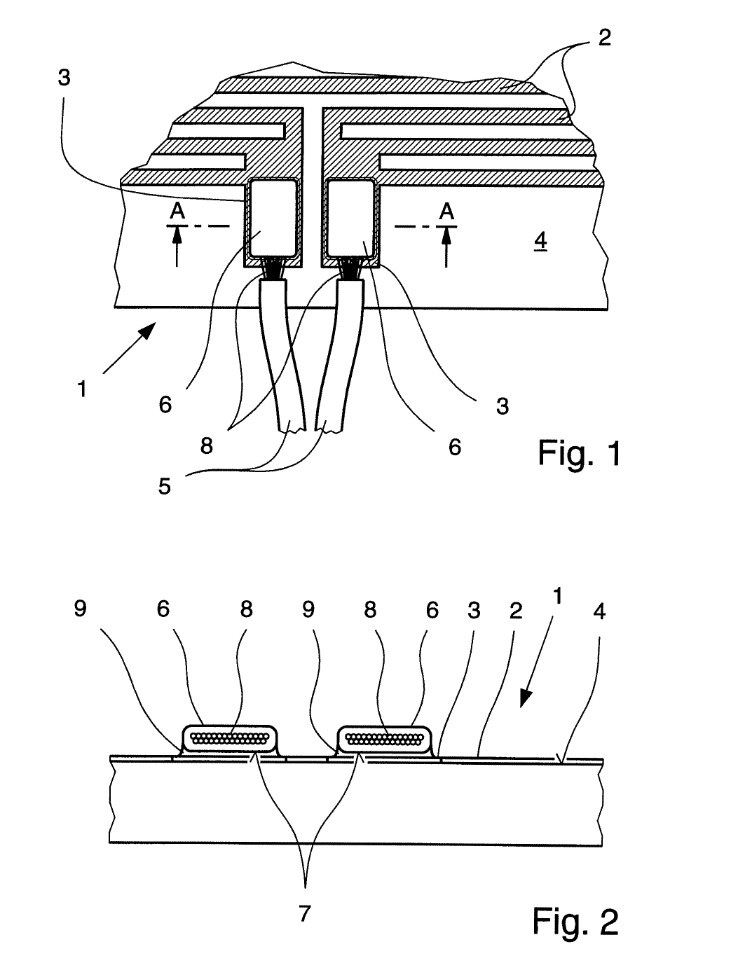

FIG. 1 shows a diagrammatic plan view of a detail of the heatable pane, with electrical terminal connections according to the invention;

FIG. 2 shows a diagrammatic sectional view through a section of the heatable pane shown in FIG. 1 along line A-A;

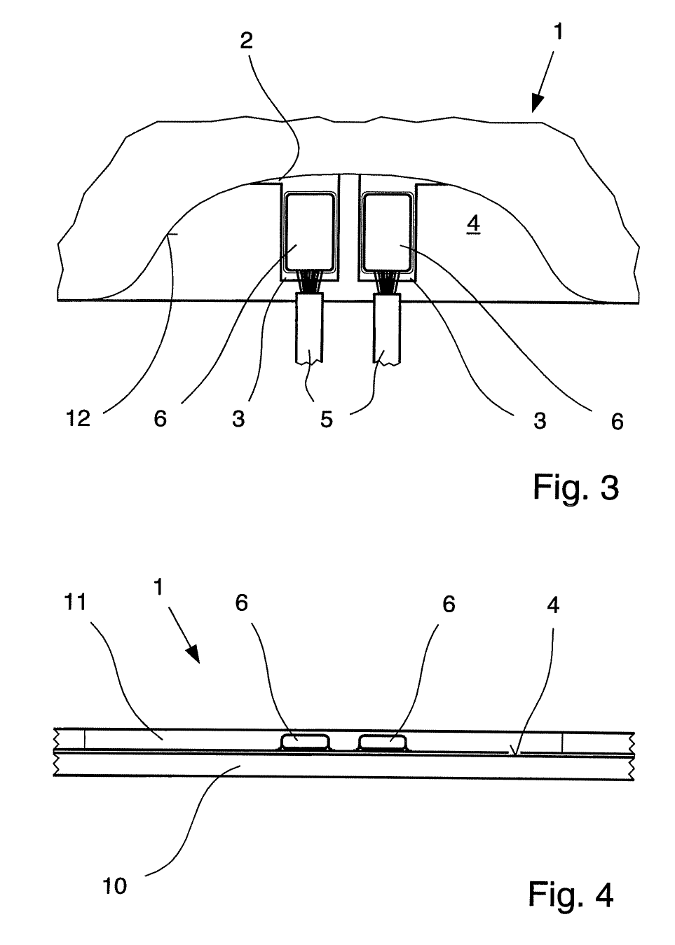

FIG. 3 shows a diagrammatic plan view of a detail of an alternative embodiment of the heatable pane according to the invention, wherein the terminal area is deposited on an internal glass pane surface of a laminated glass pane; and

FIG. 4 shows a diagrammatic sectional view through the embodiment shown in FIG. 3.

FIG. 1 shows a diagrammatic representation of a detail of a heatable pane 1 for a motor vehicle. The heatable pane 1 may be a laminated safety glass pane, such as is used in particular for windscreens, or also a toughened safety glass pane, such as is used in particular for sidelights and backlights. Arranged on a surface 4 of the glass pane is a heating element, which comprises heating conductors 2 and terminal areas 3, whereby a plurality of heating conductor 2 can be connected in parallel proceeding from terminal areas 3, as is indicated in FIG. 1. Heating conductors 2 and terminal areas 3 are formed from an electrically conductive layer deposited on glass pane surface 4. This layer is produced for example by means of a screen-printing/firing process. For this purpose, a screen printing paste with a silver content between 50 and 80 at. % (depending on the desired surface resistance), for example, is printed in a desired thickness onto (cleaned) pane surface 4. The printed-on metal-containing layer is then dried (for example in an infrared or hot-air drier). The metal-containing layer is subsequently fired at temperatures between 600° C. and 700° C. and for a period of 2 to 10 min. The heat treatment can also be combined with other heat treatments, for example during bending and/or toughening of the glass panes.

If a laminated glass is used for the glass pane, it comprises for example two float glass panes to be joined together, between which at least one plastic film, for example made of PVB, is inserted. A typical windscreen comprises two bent float glass panes each with a glass thickness of 1.5-2.1 mm and a PVB film of 0.76 mm.

Terminal wires 5 are connected to terminal areas 3 by means of soldered joints. Terminal wires 5 shown in FIG. 1 comprise a plastic-insulated flex wire, the large number of thin metal cores whereof, which preferably consist of copper, being identified by reference number 8. Metal cores 8 of the flex wire, however, are not directly soldered onto terminal areas 3, but are secured to a bending-resistant metal block 6, which then is soldered onto terminal areas 3.

In the preferred embodiment, metal blocks 6 secured to the ends of terminal wires 5 comprise metal sleeves, i.e. cable-end sleeves made of a copper alloy with a thickness of 0.5-1 mm, which are crimped onto the bared ends of terminal wires 5, in such a way that a flat, approximately rectangular parallelepiped-shaped metal block 6 with an area of approx. 6 *7 mm² and a thickness of approx. 1.5 mm is formed. The lateral faces of approx. 7 *6 mm² are flat. Moreover, the surfaces of the crimped-on metal sleeves are tinned.

FIG. 2 shows a diagrammatic sectional view through a detail of the electrical terminal connections shown in FIG. 1 along line A-A. Metal cores 8 of the flex wire of terminal wires 5 clamped into the metal sleeves can be seen here. As a result of the crimping-on of the metal sleeves onto metal cores 8, a good electrical and mechanically stable connection is produced between the metal sleeves and the flex wire.

The crimped-on metal sleeves, which, together with enclosed metal cores 8, form metal blocks 6, are soldered onto terminal areas 3 over a large area. In order to produce the soldered joint between the crimped-on metal sleeves (cable-end sleeves) and terminal areas 3 of the heating element, the following procedure is applied. A solder bead of conventional tin soldering wire (e.g. 62% Pb/25% Mn/10% Bi/3% Ag) weighing about 0.3 g is deposited manually, whilst adding flux, by means of a soldering iron at soldering iron temperatures of approx. 400° C. onto the metal-containing layer of terminal areas 3 printed onto glass surface 4. The solder bead fused onto terminal area 3 is relatively flat and has a diameter of about 6 mm. The metal sleeve to be fixed is placed in each case with a large, flat contact area 7 onto this solder bead and pressure is applied with the soldering iron on the opposite face of the metal sleeve until the solder bead lying beneath begins to melt as a result of the heat transferred via the metal sleeve. This takes place manually, the soldering time amounting to about 5 to 8 s. A relatively clean (oxide-poor) surface of the metal sleeve ensures a good heat transfer from the soldering iron to the metal sleeve and from the metal sleeve to the solder bead. For the reasons mentioned above, the temperature of the soldering iron is adjusted relatively low at about 400° C. Metal block 6 formed from the metal sleeve and clamped-in metal cores 8 not only forms a mechanical element which is stable in itself; it also represents a relatively high heat capacity with good thermal conductivity properties. This contributes towards reducing the formation of microcracks.

FIGS. 3 and 4 show an embodiment in which heating conductor 2 and terminal areas 3 are deposited on an internal surface 4 of a glass pane 10 of a laminated glass arrangement 1. In this example of embodiment, laminated glass arrangement 1 comprises two glass panes 10 and 11 joined together, between which at least one plastic film is inserted. In an edge region of laminated glass arrangement 1, in which terminal areas 3 are arranged, glass pane 11 which is not the carrier of the heating element has a recess 12, by means of which it is ensured that terminal areas 3 of the other glass pane 10 are freely accessible to allow the electrical terminal connections to be produced. In this embodiment, the overall assembly of the electrical terminal connections is not thicker than glass pane 11, so that the terminal connections do not project above the plane of the upper side of glass pane 11. This means that the thickness of metal blocks 6 is selected in such a way that the upper side of metal blocks 6 does not project above the upper side of glass pane 11, account being taken of the thickness of the conductive layer of the heating elements and the thickness of solder layer 9 between metal blocks 6 and terminal areas 3.

Numerous alternative embodiments are conceivable within the scope of the inventive idea. The glass pane can be a toughened safety glass or a laminated glass of two or more glass panes or a plastic pane. The metal-containing layer of heating conductors 2 and terminal areas 3 can be deposited on an internal or an external surface 4 of the glass panes. Furthermore a plurality of pane surfaces 4 may be provided with heating elements. The heating elements may be provided with two or more terminal areas 3. The terminal areas 3 may have a rectangular or any other shape. A plurality of heating conductors 2 may be connected in parallel between each pair of terminal areas 3.

Heating conductors 2 may also be deposited as two-dimensionally extending conductors of a transparent thin-layer system.

Instead of a solder bead deposited manually with the aid of a soldering iron, terminal areas 3 may also be provided in another way with a solder or tin layer. For example, a tin layer may be printed on and fused. The heating conductor layer preferably contains a high proportion of silver; other compositions are however also conceivable.

The terminal wires preferably comprise flex wires. Other cable designs are however also conceivable. The metal blocks are preferably produced by crimping a metal sleeve onto the flex wire. The metal sleeves may however also be soldered onto the ends of the terminal wires with the aid of a solder melting at higher temperatures.

1. A glass pane having at least one electrical functional element, wherein the functional element comprises at least one electrical conductor and at least one terminal area located at an end of the electrical conductor, wherein the electrical conductor and the terminal area are formed from an electrically conductive layer deposited on a surface of the glass pane;
wherein a terminal wire is connected to the at least one terminal area by a soldered joint,
wherein
the terminal wire is secured to a metal block having a flat contact area, and
the flat contact area is soldered on a corresponding terminal area.

2. Glass pane according to claim 1, wherein the metal block is a bending-resistant metal block.

3. Glass pane according to claim 1, wherein the contact area of the metal block has a size of at least 10 mm².

4. Glass pane according to claim 3, wherein the contact area has a maximum size of 50 mm².

5. Glass pane according to claim 3, wherein the contact area of the metal block is not greater than the terminal area of the functional element.

6. Glass pane with at least one electrical functional element according to claim 1, wherein the terminal wire is led up to the metal block in a plane essentially parallel to the contact area and leaves the metal block laterally.

7. Glass pane according to claim 6, wherein the end of the terminal wire is surrounded by the metal block.

8. Glass pane according to claim 6, wherein the contact area of the metal block has a width of at least 3 mm at right angles to the longitudinal direction of the terminal wire.

9. Glass pane according to claim 6, wherein the metal block has an approximately rectangular cross-section at right angles to the longitudinal direction of the terminal wire and is at least 1 mm thick.

10. Glass pane according to claim 6, wherein the dimension of the metal block in the longitudinal direction amounts to at least 4 mm.

11. Glass pane according to claim 1, wherein the terminal wire comprises a bundle of thin metal cores.

12. Glass pane according to claim 1, wherein the electrically conductive layer is a metal-containing layer.

13. Glass pane according claim 12, wherein the metal-containing layer contains at least 50 at. % silver.

14. Glass pane according to claim 1, wherein the glass pane surface is a surface of a laminated glass pane.

15. Glass pane according to claim 14, wherein the electrical functional element is arranged on an internal glass pane surface of a laminated glass pane comprised of two glass panes and at least one plastic film arranged therebetween.

16. Glass pane according to claim 15, wherein the glass pane not provided with the functional element is provided with a recess in a region in which the at least one terminal area is deposited on the other glass pane, through which recess the terminal area is accessible.

17. Glass pane according to claim 15, wherein the soldered-on metal block has a thickness which is smaller than the total thickness of the glass pane having the recess and the plastic film.

18. Glass pane according to claim 1, wherein the metal block is a metal sleeve crimped onto an end of the terminal wire.

19. Glass pane according to claim 18, wherein the metal sleeve has a wall thickness of 0.5-1 mm.

20. Glass pane according to claim 19, wherein the metal sleeve is made from a copper alloy and is crimped on in such a way that the metal block thereby formed has a thickness between 1.3 mm and 1.7 mm and a width between 5 and 6 mm.

21. Glass pane according to claim 19, wherein the crimped-on metal block has a tinned surface.

22. Glass pane according to claim 1, wherein the functional element is a heating element and the electrical conductor is a heating conductor, wherein the heating conductor is provided with at least two terminal areas.

23. Method of producing an electrical terminal connection to an electrical functional element on a glass pane, wherein the functional element has at least one electrical conductor and at least one terminal area located at an end of the electrical conductor, and the electrical conductor and the terminal area are formed from an electrically conductive layer deposited on a glass pane surface, the method comprising:
providing at least one terminal wire for each terminal area,
securing a bending-resistant metal block with a flat contact area at an end of the terminal wire,
depositing soldering tin onto the terminal area of the functional element and/or the contact area of the metal block, and placing and pressing the contact area of the metal block onto the terminal area such that the soldering tin is thereby fused and then allowed to cool.

24. Method according to claim 23, wherein the metal block is secured to the end of the terminal wire by pushing a metal sleeve onto the end of the terminal wire and crimping on the metal sleeve in such a way that the metal block with the flat contact area is formed.

25. Method according to claim 24, wherein the metal sleeve is crimped on in such a way that a bending-resistant metal block is formed with a contact area of at least 10 mm² and at most 50 mm².

26. Method according to claim 24, wherein the metal sleeve is crimped on in such a way that a metal block is formed with an approximately rectangular cross-section and a thickness of at least 1 mm.

27. Method according to claim 23, wherein the surface of the metal block is tinned at least in the region of the contact area before or after fixing of the terminal wire.

28. Method according to claim 23, wherein the soldering tin is deposited on the terminal area of the functional element by fusing a solder bead.

29. Glass pane according to claim 6 wherein the contact area of the metal block has a width of at least 4 mm at right angles to the longitudinal direction of the terminal wire.

30. Glass pane according to claim 6, wherein the dimension of the metal block in the longitudinal direction amounts to at least 5 mm.
